(19) United States
(12) Patent Application Publication
(10) Pub. No.: US 2014/0349423 A1
(43) Pub. Date: Nov. 27, 2014

(54) Method for Manufacturing a Liquid Crystal Display Equipment

(71) Applicants: Shih-Hsun Lo, Shenzhen (CN); Shishuai Huang, Shenzhen (CN)

(72) Inventors: Shih-Hsun Lo, Shenzhen (CN); Shishuai Huang, Shenzhen (CN)

(73) Assignee: SHENZHEN CHINA STAR OPTOELECTRONICS TECHNOLOGY CO., LTD, Shenzhen (CN)

(21) Appl. No.: 14/001,507

(22) PCT Filed: Jun. 27, 2013
(86) PCT No.: PCT/CN2013/078125

§ 371 Date: Aug. 25, 2013

(30) Foreign Application Priority Data
May 23, 2013 (CN) 201310195133.4

(51) Int. Cl. H01L 27/12; G02F 1/1339

(52) U.S. Cl. CPC H01L 27/1262; G02F 1/1339
USPC 438/27

(57) ABSTRACT

The present invention discloses a method for manufacturing a liquid crystal display. The method includes: manufacturing a matrix substrate, having a glass layer and a metal layer; manufacturing a color filter substrate, having an active area and a black matrix region; utilizing a glue to fix the matrix substrate and the color filter substrate; and utilizing a laser point light source to make a laser generated by the laser point light source only lights up a region of the matrix substrate corresponding to the glue such that heats are transferred to the glue via the metal layer of the matrix substrate to pre-solidify the glue. The present invention only lights up the region corresponding to the glue. Therefore, the present invention does not have to use a blocking plate and reduces costs.

### BACKGROUND OF THE INVENTION

1. Field of the Invention

The invention relates to a method for manufacturing a liquid crystal display equipment, and more particularly, to a method for pre-solidifying a glue when the liquid crystal display equipment is being manufactured,

2. Description of the Prior Art

Liquid crystal displays (LCD) is widely utilized in a computer, a mobile phone, and a personal digital assistant because it's thin, light, and low power consuming. Generally speaking, the LCD comprises an LCD panel and a backlight module. Because the LCD panel does not generate lights itself, the LCD panel needs the backlight module to generate lights. The liquid crystals inside the LCD panel rotate to adjust the lights generated by the backlight module such that an image can be displayed on the LCD panel.

When the LCD panel is manufactured, after the matrix substrate and the color filter substrate are manufactured, the two substrates are assembled as a case. When this procedure is proceeding, a glue should be spread between the matrix substrate and the color filter substrate to seal and fix them. The glue should be pre-solidified by ultraviolet (UV) lights and then solidified in a high-temperature oven. However, when the UV lights pre-solidifies the glue, a UV blocking plate should be used to block liquid crystals corresponding to the active area in order to prevent the light sensing unit of the liquid crystals of the active area from being pre-solidified.

Please refer to FIG. 1, which depicts a method for manufacturing an LCD panel according to the related art. When the LCD panel 100 is manufactured, a surface UV light source 110 is utilized to pre-solidify the glue 120. As mentioned previously, a layer of UV light blocking plate 130 should be used to shadow the liquid crystals of the active region such that the UV lights can only light up the region of the matrix substrate corresponding to the glue. However, the UV light block plate 130 is often manufactured by non-transparent metal, plastic, or other materials, and should be manufactured through coating, developing, etching procedures. In addition, panels having different sizes should be manufactured by using different sizes of UV light blocking plates. It raises the costs and time.

Therefore, a novel method should be introduced to solve the above-mentioned problems.

### SUMMARY OF THE INVENTION

It is therefore one of the primary objectives of the claimed invention to provide a method for manufacturing an LCD equipment, which utilizes a point light source to only light up the region corresponding to the glue without using the blocking plate. Therefore, the present invention does not need complicated procedures to produce blocking plates and thus reduces time and costs.

According to an exemplary embodiment of the claimed invention, a method for manufacturing a liquid crystal display equipment is disclosed. The method comprises:

manufacturing a matrix substrate, comprising a glass layer and a metal layer; manufacturing a color filter substrate, comprising an active area and a black matrix region; utilizing a glue to fix the matrix substrate and the color filter substrate, wherein the glue is located between the metal layer and the black matrix region; and utilizing a laser point light source and adjusting a lighting angle of a laser generated by the laser point light source by using a directivity of the laser to make the laser only light up a region of the matrix substrate corresponding to the glue without a region of the matrix substrate corresponding to the active area such that heats are transferred to the glue via the metal layer of the matrix substrate to pre-solidify the glue.

Furthermore, the laser point light source is a laser head, and the step of utilizing the laser point light source comprises: rotating the laser head to make the laser generated by the laser head repeatedly light up the region of the matrix substrate corresponding to the glue.

Furthermore, the metal layer is a non-transparent metal layer.

Furthermore, the method further comprises: utilizing a plurality of laser point light sources to simultaneously light up the region of the matrix substrate corresponding to the glue to pre-solidify the glue.

According to an exemplary embodiment of the claimed invention, a method for manufacturing a liquid crystal display equipment is disclosed. The method comprises: manufacturing a matrix substrate, comprising a glass layer and a metal layer having holes; manufacturing a color filter substrate; utilizing a glue to fix the matrix substrate and the color filter substrate, wherein the glue is located at a position corresponding to the metal layer; and utilizing a point light source to generate a light having a specific wavelength and utilizing the light to light up the region of the matrix substrate corresponding to the glue such that the light is transferred to the glue via the holes of the metal layer to pre-solidify the glue.

Furthermore, the light having the specific wavelength is an ultraviolet light.

Furthermore, the point light source is located inside a reflection cavity to focus the ultraviolet light.

Furthermore, the point light source is fixed on a XY table machine, and the step of utilizing the point light source comprises: moving the XY table machine to move the point light source along a route of the region of the matrix substrate corresponding to the glue such that the light lights up the glue to pre-solidify the glue.

Furthermore, the method further comprises: utilizing a plurality of point light sources to pre-solidify the glue.

Furthermore, the method further comprises: independently moving the point light sources along a route of the region of the matrix substrate corresponding to the glue such that lights generated by the point light sources light up the glue to pre-solidify the glue.

In contrast to the related art, the present invention provides a method for manufacturing an LCD equipment, which utilizes a point light source to only light up the region corresponding to the glue without using the blocking plate. Therefore, the present invention does not need complicated procedures to produce blocking plates and thus reduces time and costs.

These and other objectives of the claimed invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 depicts a method for manufacturing an LCD panel according to the related art.

FIG. 2 depicts a method for manufacturing an LCD panel according to a first embodiment of the present invention.

FIG. 3 depicts a scanning route of the laser point light source shown in FIG. 2.

FIG. 4 depicts a method for manufacturing an LCD panel according to a second embodiment of the present invention.

FIG. 5 depicts a scanning route of the point UV light source shown in FIG. 4.

FIG. 6 depicts a method for manufacturing an LCD panel by using point UV light source according to another embodiment of the present invention.

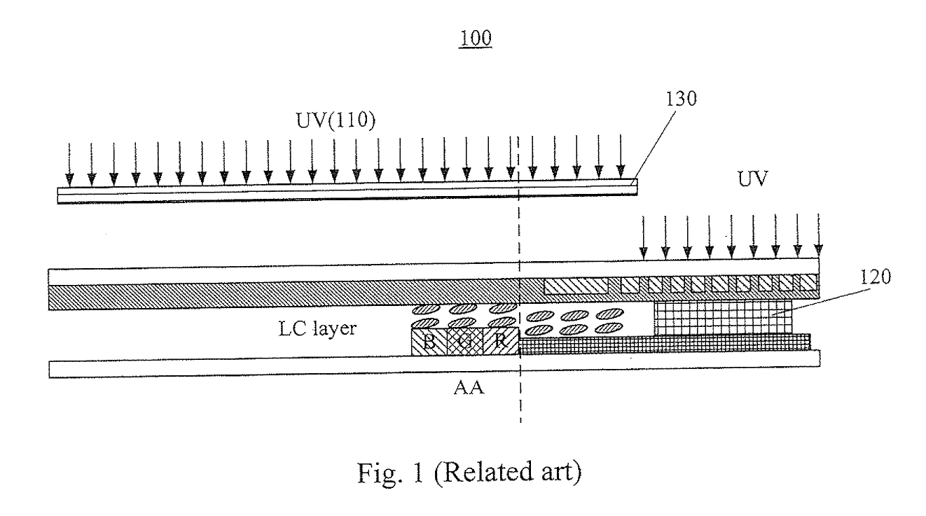

### DETAILED DESCRIPTION OF THE PREFERRED EMBODIMENT

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

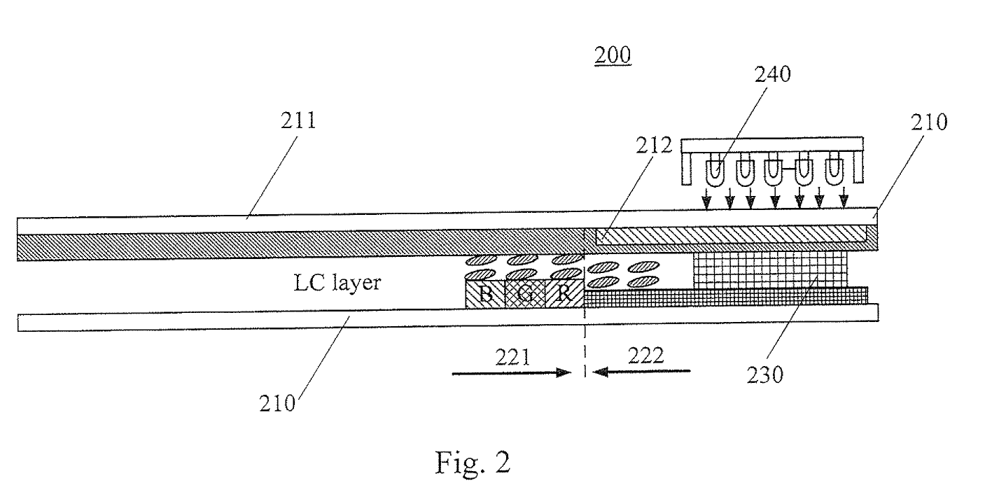

Please refer to FIG. 2, which depicts a method for manufacturing an LCD panel according to a first embodiment of the present invention. The LCD display panel 200 comprises a matrix substrate 210 and a color filter substrate 220. The matrix substrate 210 comprises a glass layer 211 and a metal layer 212. An active region 221 and a black matrix region 222 are defined on the color filter substrate 220.

As mentioned previously, a glue 230 should be spread between the matrix substrate 210 and the color filter substrate 220 in order to seal and fix them. As shown in FIG. 2, the glue 230 is located between the metal layer 212 of the matrix substrate 210 and black matrix region 222 of the color filter substrate 220.

Please note, the present utilizes a different method to pre-solidify the glue 230. In this embodiment, the present invention utilizes a laser point light source 240. As known by those skilled in the art, the laser has a directivity. Therefore, the present invention utilizes the directivity of the laser to make the laser only light up the region of the matrix substrate 210 corresponding to the glue 230. In this embodiment, the laser point light source 240 can be a laser head. By rotating the laser head, the present invention can limits the laser generated by the laser head to repeatedly light up the region of the matrix substrate 210 corresponding to the glue 230 without the portion of the matrix substrate 210 corresponding to the active area 221.

In a preferred embodiment, the metal layer 211 has no holes in it. When the lasers generated by the laser point light source 240 lights up the metal layer 211, the metal layer 211 transfers the heats to a lower-layer glue 210 such that the glue 230 is pre-solidified. In addition, because the present invention utilizes the directivity of the laser to perform the pre-solidification, it can prevent the laser from lighting up the region corresponding to the active area 221 without using the blocking plate. Therefore, the present invention can solve the problem of pre-solidifying the liquid crystals of the active area.

Please note, in the above-mentioned embodiment, only one laser point light source 230 is utilized. However, this is not a limitation of the present invention. In the actual implementation, a plurality of laser point light sources 230 can be simultaneously utilized to repeatedly scan the region of the matrix substrate 210 corresponding to the glue 230. This change also obeys the spirit of the present invention.

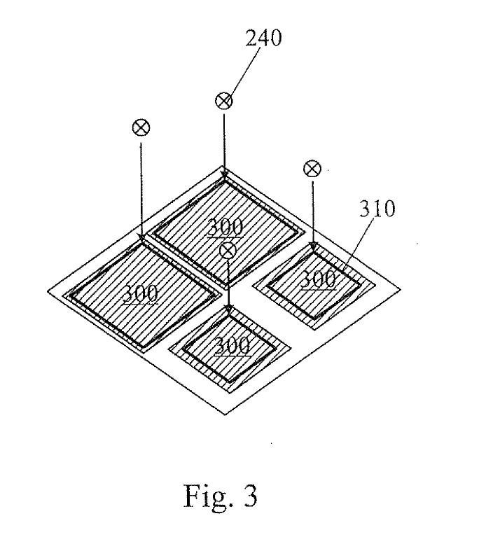

Please refer to FIG. 3, which depicts a scanning route of the laser point light source 240 shown in FIG. 2. The present invention can manufacture a plurality of LCD panels 300 at the same time. In FIG. 3, the rectangular route 310 is the scanning route of the laser. That is, the scanning route is the above-mentioned region corresponding to the glue 230. The laser repeatedly scans the scanning route such that the heats can be transferred to the glue 230 to complete the pre-solidification of the glue frame 230.

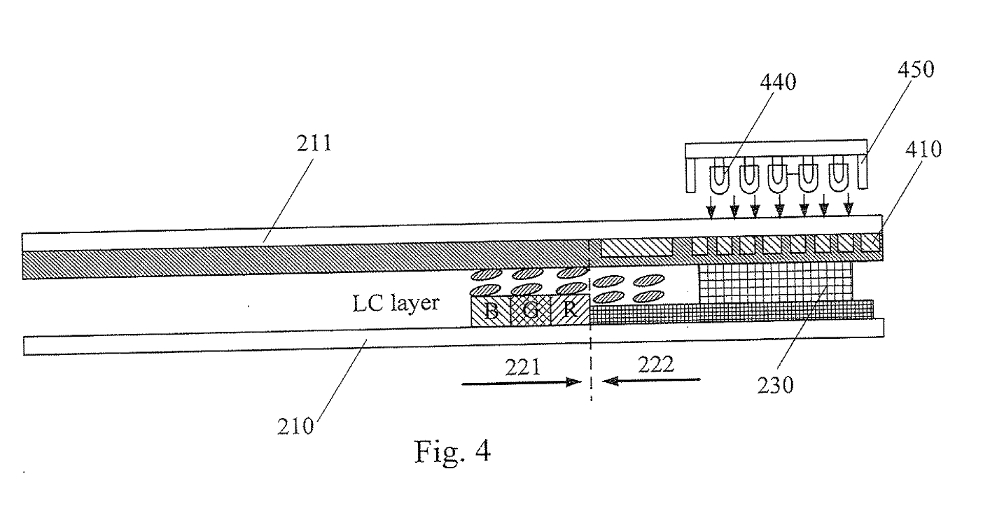

Please refer to FIG. 4, which depicts a method for manufacturing an LCD panel according to a second embodiment of the present invention. The LCD display panel 200 comprises a matrix substrate 210 and a color filter substrate 220. The matrix substrate 210 comprises a glass layer 211 and a metal layer 410. An active region 221 and a black matrix region 222 are defined on the color filter substrate 220.

As mentioned previously, a glue 230 should be spread between the matrix substrate 210 and the color filter substrate 220 in order to seal and fix them. As shown in FIG. 4, the glue 230 is located between the metal layer 410 of the matrix substrate 210 and black matrix region 222 of the color filter substrate 220.

The difference between this embodiment and the first embodiment is: in this embodiment, the present invention utilizes a point ultraviolet (UV) light source 440 to pre-solidify the glue 230. Please note, the point ultraviolet (UV) light source 440 does not have directivity as the laser. Therefore, in this embodiment, the point UV light source 440 is located inside a reflection cavity to use the reflection cavity to focus the UV lights on a lower point. In this way, as long as the point UV light source 440 is repeatedly moved along the region of the matrix substrate 210 corresponding to the glue 230, the same effect of the laser can be achieved. In a preferred embodiment, the point UV light source 440 is fixed on an XY table machine. In this way, the XY table machine can repeatedly move point UV light source 440 along a predetermined route such that the point UV light source 440 can only light up the region of the matrix substrate 210 corresponding to the glue 230.

In a preferred embodiment, the metal layer 410 has holes in it. Therefore, when the UV lights 440 generated by the point UV light source 440 repeatedly light up the metal layer 410, the UV lights directly light up the lower-layer glue 230 via the holes of the metal layer 410 such that the glue 230 is pre-solidified.

Similarly, according to the above-mentioned mechanism, the present invention does not need to use the blocking plate to prevent the UG lights from lighting up a region corresponding to the active area 221. Therefore, the present invention can solve the problem of pre-solidifying the liquid crystals corresponding to the active area.

Please note, in the above-mentioned embodiment, only one point UV light source 430 is utilized. However, this is not a limitation of the present invention. In the actual implementation, a plurality of point UV light sources 430 can be used to repeatedly scan the region of the matrix substrate 210 corresponding to the glue 230. This change also obeys the spirit of the present invention.

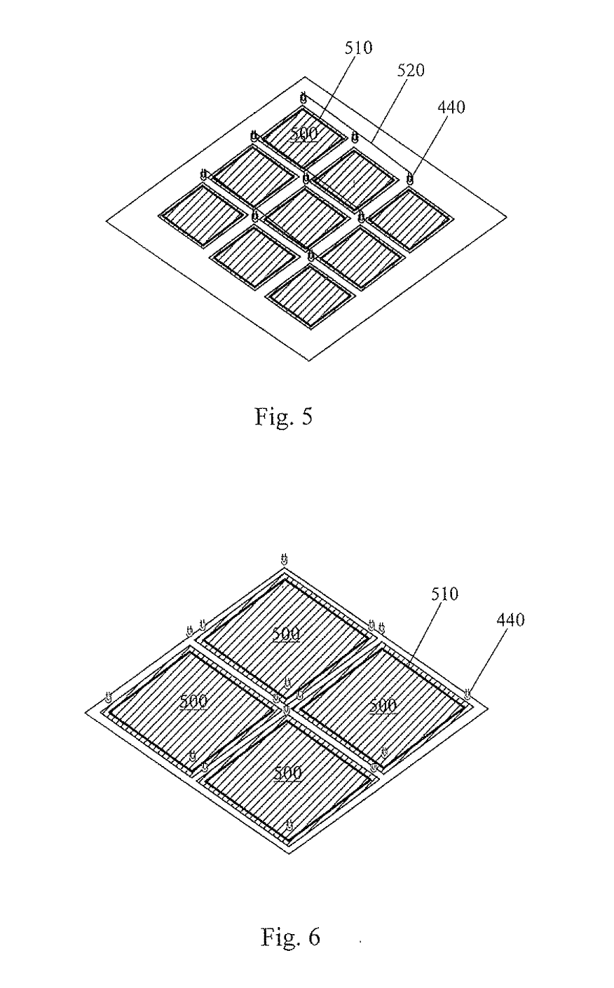

Please refer to FIG. 5, which depicts a scanning route 440 of the point UV light source shown in FIG. 4. The present invention can manufacture a plurality of LCD panels 500 at the same time. In FIG. 5, the rectangular route 510 is the scanning route of the point UV light source 440, and also the region corresponding to the glue 230. As shown in FIG. 5, the point UV light sources 440 are fixed on the XY table machine 520, and the XY table machine 520 moves the point UV light sources 440 to make them repeatedly scan the scanning route 510. In this way, the UV lights can directly light up the glue 230 and complete the pre-solidification of the glue frame 230,

Please note, in the above-mentioned embodiment, the point UV light source 440 is fixed on the XY table machine. However, this is not a limitation of the present invention. In the actual implementation, the present invention can utilize all kinds of methods to make the point UV light source 440 move along a predetermined scanning route. This change also obeys the spirit of the present invention.

Please refer to FIG. 6, which depicts a method for manufacturing an LCD panel by using point UV light source according to another embodiment of the present invention. As shown in FIG. 6, the point UV light sources 440 are not fixed on the XY table machine. Instead, they can move independently. In addition, the number of the point UV light sources 440 is more than the number of the point UV light sources 440 shown in FIG. 5. These point UV light sources 440 independently moves along the scanning route 510 to complete the pre-solidification of the glue. For example, the point UV light sources 440 can move clockwise or counter-clockwise along the scanning route 510 to complete the pre-solidification of the glue.

In contrast to the related art, the present invention provides a method for manufacturing an LCD equipment, which utilizes a point light source to only light up the region corresponding to the glue without using the blocking plate. Therefore, the present invention does not need complicated procedures to produce blocking plates and thus reduces time and costs.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A method for manufacturing a liquid crystal display equipment, the method comprising:
manufacturing a matrix substrate, comprising a glass layer and a metal layer;
manufacturing a color filter substrate, comprising an active area and a black matrix region;
utilizing a glue to fix the matrix substrate and the color filter substrate, wherein the glue is located between the metal layer and the black matrix region; and
utilizing a laser point light source and adjusting a lighting angle of a laser generated by the laser point light source by using a directivity of the laser to make the laser only light up a region of the matrix substrate corresponding to the glue without a region of the matrix substrate corresponding to the active area such that heats are transferred to the glue via the metal layer of the matrix substrate to pre-solidify the glue.

2. The method of claim 1, wherein the laser point light source is a laser head, and the step of utilizing the laser point light source comprises: rotating the laser head to make the laser generated by the laser head repeatedly light up the region of the matrix substrate corresponding to the glue.

3. The method of claim 1, wherein the metal layer is a non-transparent metal layer.

4. The method of claim 1, further comprising:
utilizing a plurality of laser point light sources to simultaneously light up the region of the matrix substrate corresponding to the glue to pre-solidify the glue.

5. A method for manufacturing a liquid crystal display equipment, the method comprising:
manufacturing a matrix substrate, comprising a glass layer and a metal layer having holes;
manufacturing a color filter substrate;
utilizing a glue to fix the matrix substrate and the color filter substrate, wherein the glue is located at a position corresponding to the metal layer; and
utilizing a point light source to generate a light having a specific wavelength and utilizing the light to light up the region of the matrix substrate corresponding to the glue such that the light is transferred to the glue via the holes of the metal layer to pre-solidify the glue.

6. The method of claim 5, wherein the light having the specific wavelength is an ultraviolet light.

7. The method of claim 6, wherein the point light source is located inside a reflection cavity to focus the ultraviolet light.

8. The method of claim 7, wherein the point light source is fixed on a XY table machine, and the step of utilizing the point light source comprises:
moving the XY table machine to move the point light source along a route of the region of the matrix substrate corresponding to the glue such that the light lights up the glue to pre-solidify the glue.

9. The method of claim 5, further comprising:
utilizing a plurality of point light sources to pre-solidify the glue.

10. The method of claim 9, further comprising:
independently moving the point light sources along a route of the region of the matrix substrate corresponding to the glue such that lights generated by the point light sources light up the glue to pre-solidify the glue.
